(19) United States
(12) Patent Application Publication
(10) Pub. No.: US 2017/0326850 A1
(43) Pub. Date: Nov. 16, 2017

(54) LAMINATE PRODUCTION METHOD, SUBSTRATE PROCESSING METHOD, AND LAMINATE

(71) Applicant: Tokyo Ohka Kogyo Co., Ltd., Kawasaki-shi (JP)

(72) Inventors: Takahiro YOSHIOKA, Kawasaki-shi (JP); Koki TAMURA, Kawasaki-shi (JP); Hirofumi IMAI, Kawasaki-shi (JP); Atsushi KUBO, Kawasaki-shi (JP)

(73) Assignee: Tokyo Ohka Kogy Co., Ltd., Kawasaki-shi (JP)

(21) Appl. No.: 15/531,527

(22) PCT Filed: Oct. 29, 2015
(86) PCT No.: PCT/JP2015/080609

§ 371 Date: May 30, 2017

(30) Foreign Application Priority Data
Dec. 3, 2014 (JP) 2014-245403

(51) Int. Cl. B32B 27/28; H01L 21/02; B32B 37/12; C09J 7/02; C09J 181/06

(52) U.S. Cl. CPC B32B 27/283; B32B 37/12; H01L 21/02381; C09J 7/025; H01L 21/02008; B32B 27/286; B32B 2457/14; C09J 181/06; C09J 2400/10; C09J 2481/00; C09J 2483/005; C09J 2203/326

(57) ABSTRACT

A production method of a laminate including a substrate and a light-transmitting support plate that are laminated each other via an adhesive layer and a release layer that is altered through absorption of light, the method including a release layer forming step of coating a reactive polysilsesquioxane on a surface of the support plate, the surface being opposed to the substrate, and heating the reactive polysilsesquioxane to perform polymerization, thereby forming the release layer.

### TECHNICAL FIELD

The present invention relates to a method of producing a laminate, a method of processing a substrate, and a laminate.

### BACKGROUND ART

In recent years, thinning, miniaturization, weight reduction, and so on of electronic instruments, such as IC cards, mobile phones, etc., are demanded. In order to satisfy these demands, with respect to semiconductor chips to be installed, thin semiconductor chips must be used. For this reason, though a thickness (film thickness) of a wafer substrate serving as a base of the semiconductor chip is 125 μm to 150 μm in the existing circumstances, it is said that it must be reduced to 25 μm to 50 μm for next-generation chips. In consequence, in order to obtain a wafer substrate having the above-described film thickness, a process of thinning the wafer substrate is absolutely essential.

In the wafer substrate, its strength is lowered due to thinning. Therefore, in order to prevent damage of the thinned wafer substrate from occurring, a structure, such as a circuit, etc., is mounted on the wafer substrate while undergoing automatic transportation in a state of bonding a support plate on the wafer substrate during a production process. For example, in the wafer substrate, a through electrode is formed by a lithography process or the like, and a semiconductor power device is produced by an ion diffusion process and an annealing process, and so on.

In the case of firmly adhering a wafer substrate and a support to each other, it is difficult to separate the support from the wafer substrate without damaging a structure mounted on the wafer substrate depending on an adhesive (adhesive material). In consequence, a very difficult temporary fixing technology in which while realizing the firm adhesion between the wafer substrate and the support during a production process, after the production process, a structure mounted on the wafer substrate, such as an element, etc., is separated without being damaged is demanded to be developed.

In PTL 1, a second temporary adhesive material layer which is releasablly bonded to the support plate and which is made of a thermosetting modified siloxane polymer layer is provided, and the wafer substrate and the support plate are separated from each other by heating the second temporary adhesive material layer or applying a mechanical stress thereto.

In addition, in PTL 2, a release layer containing a silsesquioxane skeleton, a siloxane skeleton, or an alkoxy titanium skeleton is provided, and the wafer substrate and the support plate are separated from each other through alteration upon irradiation of the release layer with light.

### CITATION LIST

### Patent Literature

PTL 1: Japanese Patent Application Publication, Tokukai, No. 2013-235939 A (Publication Date: Nov. 21, 2013)

PTL 2: Japanese Patent Application Publication, Tokukai, No. 2012-124467 A (Publication Date: Jun. 28, 2012)

### SUMMARY OF INVENTION

### Technical Problem

PTL 1 does not disclose at all technical details regarding the use of the thermosetting modified siloxane polymer layer as the release layer to be altered upon irradiation with light.

In addition, in a wafer handling system in which a laminate is formed, and various processings are applied to the substrate, the laminate is required to include a release layer having higher chemical resistance than the laminate described in PTL 2 as well as high heat resistance.

In view of the above-described problems, the present invention has been made, and an object thereof is to provide a laminate including a release layer having high heat resistance and high chemical resistance, and technologies related thereto.

### Solution to Problem

A production method of a laminate according to the present invention is a method of producing a laminate in which a substrate and a light-transmitting support are laminated via an adhesive layer and a release layer that is altered through absorption of light, the method including a release layer forming step of coating a reactive polysilsesquioxane on a surface of the support, the surface being opposed to the substrate, and heating the reactive polysilsesquioxane to perform polymerization, thereby forming the release layer.

In addition, a method of processing a substrate according to the present invention includes a release layer forming step of coating a reactive polysilsesquioxane on a substrate or a support made of silicon and heating the reactive polysilsesquioxane to perform polymerization, thereby forming a release layer that is altered through absorption of light; a laminate production step of laminating the substrate and the support via an adhesive layer and the release layer to produce a laminate; and a separation step of, after the laminate production step, irradiating light having a wavelength of 9 μm or more and 11 μm or less to alter the release layer and separating the support from the laminate.

In addition, a laminate according to the present invention is a laminate including a substrate and a support which supports the substrate that are laminated each other via an adhesive layer and a release layer that is altered through absorption with light, the release layer being formed of a polymer of a reactive polysilsesquioxane.

### Advantageous Effects of Invention

In accordance with the present invention, it is possible to provide a laminate including a release layer having high heat resistance and high chemical resistance, and technologies related thereto.

### BRIEF DESCRIPTION OF DRAWING

FIG. 1 is a view schematically illustrating a method of producing a laminate and a method of processing a substrate according to embodiments of the present invention.

### DESCRIPTION OF EMBODIMENTS

<Production Method of Laminate>

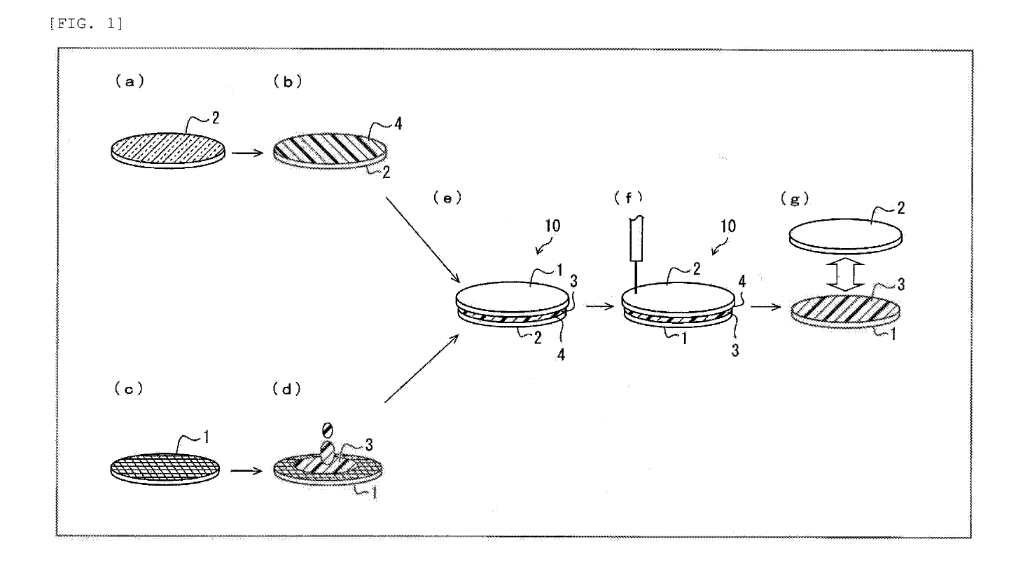

A method of producing a laminate 10 according to an embodiment of the present invention is described in detail by reference to (a) to (e) of FIG. 1.

As illustrated in (a) and (b) of FIG. 1, the production method of the laminate 10 according to the present embodiment includes a release layer forming step of coating a solution containing a reactive polysilsesquioxane on a surface of a support plate 2, the surface being opposed to a substrate 1, and heating the reactive polysilsesquioxane to perform polymerization, thereby forming a release layer 4.

In accordance with the above-described configuration, a polymer of the reactive polysilsesquioxane can be formed as the release layer 4 on the support plate 2. In the release layer forming step, by polymerizing the reactive polysilsesquioxane, high chemical resistance and high heat resistance can be brought to the release layer 4.

In addition, the production method of the laminate 10 according to the present embodiment includes an adhesive layer forming step of forming an adhesive layer 3 on the substrate 1 ((c) and (d) of FIG. 1) and a lamination step of laminating the substrate 1 and the support plate 2 via the adhesive layer 3 and the release layer 4 ((e) of FIG. 1).

According to this, the laminate 10 including the release layer 4 having high chemical resistance and high heat resistance can be produced.

In addition, in the production method of the laminate 10 according to the present embodiment, the laminate 10 that supports the substrate 1 made of silicon by the support plate 2 made of silicon is produced.

[Release Layer Forming Step]

In the release layer forming step, a solution of a reactive polysilsesquioxane dissolved in a solvent is coated on the support plate 2 as illustrated in (a) of FIG. 1. Thereafter, by heating the support plate 2 having the solution coated thereon, the reactive polysilsesquioxane is polymerized. According to this, the release layer 4 is formed on the support plate 2 as illustrated in (b) of FIG. 1.

Examples of a method of coating the solution of the reactive polysilsesquioxane on the support plate 2 may include spin coating, dipping, roller blade coating, spray coating, slit coating, and the like. In addition, though a concentration of the reactive polysilsesquioxane in the solution may be properly regulated according to the coating method of solution, it may be in a range of 1% by weight or more and 50% by weight or less.

In addition, in the release layer forming step, by heating the reactive polysilsesquioxane coated on the support plate 2, the reactive polysilsesquioxane on the support plate 2 is polymerized. According to this, the polysilsesquioxane molecules of forming the release layer 4 are crosslinked with each other, whereby the chemical resistance and heat resistance of the release layer 4 can be enhanced.

In the release layer forming step, a temperature for heating the reactive polysilsesquioxane is preferably 100° C. or higher and 500° C. or lower, and more preferably 200° C. or higher and 400° C. or lower. When the reactive polysilsesquioxane is heated at a temperature of 100° C. or higher and 500° C. or lower, the reactive polysilsesquioxane can be suitably polymerized, and the heat resistance and chemical resistance of the release layer 4 can be enhanced.

In addition, a time for heating the reactive polysilsesquioxane is preferably 5 minutes or more and 120 minutes or less, and more preferably 30 minutes or more and 120 minutes or less. When the time for heating the reactive polysilsesquioxane is 5 minutes or more and 120 minutes or less, the solvent can be evaporated and thoroughly removed from the release layer 4 by the heat while allowing the reactive polysilsesquioxane to suitably react. In addition, moisture that is a by-product generated when the reactive polysilsesquioxane is polymerized can be suitably removed. In consequence, after forming the laminate 10, the generation of a void between the support plate 2 and the release layer 4 by the solvent or moisture or the like remaining in the release layer 4 can be prevented from occurring.

A thickness of the release layer 4 is, for example, more preferably 0.05 to 50 μm, and still more preferably 0.3 to 1 μm. When the thickness of the release layer 4 falls within a range of 0.05 to 50 μm, the processing can be performed without causing a fault in the heating step and on the occasion of stripping. In addition, it is especially preferred that the thickness of the release layer 4 falls within a range of 1 μm or less from the viewpoint of productivity.

### [Support Plate 2]

The support plate (support) 2 is one for supporting the substrate 1 for the purpose of preventing damage or deformation of the substrate from occurring at a process time for thinning of the substrate, transportation, mounting, or the like ((a) of FIG. 1).

In the production method of a laminate according to the present embodiment, the support plate 2 is formed of a material made of silicon. By using the support plate 2 made of silicon, the substrate 1 can be suitably supported. In addition, the support plate 2 made of silicon is able to transmit light having a wavelength capable of altering the release layer 4 which is obtained through polymerization of the reactive polysilsesquioxane.

### [Release Layer 4]

The release layer 4 is a layer which is formed through polymerization of the reactive polysilsesquioxane by means of heating and can be altered upon irradiation with light.

In the present specification, what the release layer 4 is “altered” means a phenomenon in which the release layer 4 is rendered in a state where it may be broken upon receipt of a little external force, or a state where an adhesive force to the layer in contact with the release layer 4 is lowered. As a result of alteration of the release layer 4 generated through absorption of light, the release layer 4 loses the strength or adhesiveness before receipt of irradiation with light. Namely, the release layer 4 becomes brittle through absorption of light. The alteration of the release layer 4 may be the matter that the polymer of the reactive polysilsesquioxane causes decomposition due to energy of the absorbed light, change of steric configuration, dissociation of a functional group, or the like. The alteration of the release layer 4 is generated as a result of absorption of light.

Accordingly, for example, by altering the release layer 4 such that it is broken only by lifting up the support plate 2, the support plate 2 and the substrate 1 can be easily separated from each other. More specifically, for example, using a supporting member separation apparatus or the like, by fixing one of the substrate 1 and the support plate 2 in the laminate 10 on a pedestal and holding and lifting up the other by an adsorption pad including an adsorption unit (holding unit) or the like, the support plate 2 and the substrate 1 may be separated from each other, or by grasping a chamfer site of the peripheral edge part of the support plate 2 by a separation plate including a clamp (claw part) to apply a force, the substrate 1 and the support plate 2 may be separated from each other. In addition, for example, the support plate 2 may also be stripped from the substrate 1 in the laminate 10 by a supporting member separation apparatus including a stripping unit of feeding a stripping solution for stripping the adhesive. By feeding the stripping solution into at least a part of the peripheral edge part of the adhesive layer 3 in the laminate 10 by the stripping unit and swelling the adhesive layer 3 in the laminate 10 to concentrate a force in the release layer 4 from a swollen part of the adhesive layer 3, the force can be applied to the substrate 1 and the support plate 2. For this reason, the substrate 1 and the support plate 2 can be suitably separated from each other.

Moreover, the force to be applied to the laminate may be properly regulated according to a size or the like of the laminate and is not limited. However, for example, so far as a laminate having a diameter of approximately 300 mm is concerned, by applying a force of approximately 1 kgf, the substrate and the support plate can be suitably separated from each other.

### (Reactive Polysilsesquioxane)

The reactive polysilsesquioxane as referred to in the present specification is a polysilsesquioxane having a silanol group or a functional group capable of forming a silanol group through hydrolysis in a terminal of a polysilsesquioxane skeleton and is one in which molecules thereof can be polymerized with each other through condensation of the silanol group or the functional group capable of forming a silanol group. In addition, when the reactive polysilsesquioxane includes a silanol group or a functional group capable of forming a silanol group, those including a silsesquioxane skeleton, such as a random structure, a basket structure, a rudder structure, etc., can be adopted.

In addition, it is more preferred that the reactive polysilsesquioxane has a structure represented by the following formula (1).

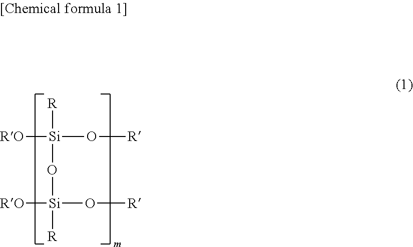

In the formula (1), plural R's each independently is selected from the group consisting of a hydrogen atom and an alkyl group having 1 or more and 10 or less carbon atoms, and more preferably selected from the group consisting of a hydrogen atom and an alkyl group having 1 or more and 5 or less carbon atoms. When R′ is a hydrogen atom or an alkyl group having 1 or more and 10 or less carbon atoms, the reactive polysilsesquioxane represented by the formula (1) can be suitably condensed upon heating in the release layer forming step.

In the formula (1), m is preferably an integer of 1 or more and 100 or less, and more preferably an integer of 1 or more and 50 or less. When the reactive polysilsesquioxane includes a repeating unit represented by the formula (1), the release layer 4 having a high content of an Si—O bond and a high absorbance of infrared rays (0.78 μm or more 1,000 μm or less), preferably far-infrared rays (3 μm or more and 1,000 μm or less), and more preferably light having a wavelength of 9 μm or more and 11 μm or less can be formed as compared with the formation using other materials.

In addition, in the formula (1), plural Rs, which may be the same as or different from each other, each independently is an organic group. Here, R is, for example, an aryl group, an alkyl group, an alkenyl group, or the like, and such an organic group may have a substituent.

In the case where R is an aryl group, examples thereof may include a phenyl group, a naphthyl group, an anthryl group, a phenanthryl group, and the like, with a phenyl group being more preferred. In addition, the aryl group may be bonded to the polysilsesquioxane skeleton via an alkylene group having 1 to 5 carbon atoms.

In the case where R is an alkyl group, examples of the alkyl group may include a linear, branched, or cyclic alkyl group. In addition, in the case where R is an alkyl group, the carbon number is preferably 1 to 15, and more preferably 1 to 6. In addition, in the case where R is a cyclic alkyl group, it may be an alkyl having a monocyclic or di- to tetracyclic structure.

Similar to the case where R is an alkyl group, in the case where R is an alkenyl group, examples thereof may include a linear, branched, or cyclic alkenyl group. The carbon number of the alkenyl group is preferably 2 to 15, and more preferably 2 to 6. In addition, in the case where R is a cyclic alkenyl group, it may be an alkenyl group having a monocyclic or di- to tetracyclic structure. Examples of the alkenyl group may include a vinyl group, an allyl group, and the like.

In addition, examples of the substituent which R may have may include a hydroxyl group, an alkoxy group, and the like. In the case where the substituent is an alkoxy group, examples thereof may include a linear, branched, or cyclic alkylalkoxy group. The carbon number in the alkoxy group is preferably 1 to 15, and more preferably 1 to 10.

In addition, from one viewpoint, the siloxane content of the reactive polysilsesquioxane is preferably 70 mol % or more and 99 mol % or less, and more preferably 80 mol % or more and 99 mol % or less. When the siloxane content of the reactive polysilsesquioxane is 70 mol % or more and 99 mol % or less, a release layer which can be suitably altered upon irradiation with infrared rays (preferably far-infrared rays, and more preferably light having a wavelength of 9 μm or more and 11 μm or less) can be formed.

In addition, from one viewpoint, an average molecular weight (Mw) of the reactive polysilsesquioxane is preferably 500 or more and 50,000 or less, and more preferably 1,000 or more and 10,000 or less. When the average molecular weight (Mw) of the reactive polysilsesquioxane is 1,000 or more and 10,000 or less, the reactive polysilsesquioxane can be suitably dissolved in a solvent and can be suitably coated on the support.

Examples of a commercially available product that can be used as the reactive polysilsesquioxane may include SR-13, SR-21, SR-23, and SR-33, all of which are manufactured by Konishi Chemical Ind. Co., Ltd., and the like.

### (Solvent)

The solvent may be one capable of dissolving the reactive polysilsesquioxane therein, and the following solvents can be used.

Examples of the solvent may include linear hydrocarbons, such as hexane, heptane, octane, nonane, methyloctane, decane, undecane, dodecene, and tridecane; branched hydrocarbons having 4 to 15 carbon atoms; cyclic hydrocarbons, such as cyclohexane, cycloheptane, cyclooctane, naphthalene, decahydronaphthalene, and tetrahydronaphthalene; terpene-based solvents, such as p-menthane, o-menthane, m-menthane, diphenylmenthane, 1,4-terpene, 1,8-terpene, bornane, norbornane, pinane, thujane, carane, longifolene, geraniol, nerol, linalool, citral, citronellol, menthol, isomenthol, neomenthol, α-terpineol, β-terpineol, γ-terpineol, terpinen-1-ol, terpinen-4-ol, dihydroterpinyl acetate, 1,4-cineol, 1,8-cineol, borneol, carvone, ionone, thujone, camphor, d-limonene, 1-limonene, and dipentene; lactones, such as γ-butyrolactone; ketones, such as acetone, methyl ethyl ketone, cyclohexanone (CH), methyl-n-pentyl ketone, methyl isopentyl ketone, and 2-heptanone; polyhydric alcohols, such as ethylene glycol, diethylene glycol, propylene glycol, and dipropylene glycol; derivatives of polyhydric alcohols, such as compounds having an ester bond, e.g., ethylene glycol monoacetate, diethylene glycol monoacetate, propylene glycol monoacetate, dipropylene glycol monoacetate, etc., compounds having an ether bond, e.g., monoalkyl ethers or monophenyl ethers, e.g., monomethyl ethers, monoethyl ethers, monopropyl ethers, monobutyl ethers, or the like of the above-described polyhydric alcohols or the above-described compounds having an ester bond, etc.; cyclic ethers, such as dioxane; esters, such as methyl lactate, ethyl lactate (EL), methyl acetate, ethyl acetate, butyl acetate, methoxybutyl acetate, methyl pyruvate, ethyl pyruvate, methyl methoxypropionate, and ethyl ethoxypropionate; aromatic organic solvents, such as anisole, ethyl benzyl ether, cresyl methyl ether, diphenyl ether, dibenzyl ether, phenetol, and butyl phenyl ether; and the like.

The solvent is preferably a derivative of a polyhydric alcohol. Examples of the derivative of a polyhydric alcohol include propylene glycol monomethyl ether acetate (PGMEA), propylene glycol monomethyl ether (PGME), and the like. Of these, PGMEA or PGME is preferred, and PGMEA is more preferred.

### [Adhesive Layer Forming Step]

In the adhesive layer forming step, an adhesive is coated on the substrate 1 as illustrated in (C) of FIG. 1, thereby forming the adhesive layer 3 ((d) of FIG. 1).

The adhesive layer 3 is used for the purpose of bonding the substrate 1 and the support plate 2 to each other. The adhesive layer 3 can be formed by coating the adhesive by a method, such as spin coating, dipping, roller blade coating, spray coating, slit coating, etc. In addition, for example, instead of coating the adhesive directly on the substrate 1, the adhesive layer 3 may also be formed by bonding a film, on both surfaces of which have been previously coated an adhesive (so-called a pressure sensitive adhesive double coated tape), onto the substrate 1.

A thickness of the adhesive layer 3 may be properly set according to the kinds of the substrate 1 and the support plate 2 which are subjective to bonding, a processing to be applied on the substrate 1 after bonding, and so on is preferably in a range of 10 to 150 μm, and more preferably in a range of 15 to 100 μm.

### [Substrate 1]

The substrate 1 may be subjected to a process, such as thinning, mounting, etc., in a state where it is supported by the support plate 2. In the production method of a laminate according to the present embodiment, a silicon wafer is used as the substrate 1.

### [Adhesive Layer 3]

The adhesive layer 3 is used for the purpose of bonding the substrate 1 and the support plate 2 to each other.

As for the adhesive for forming the adhesive layer 3, various adhesives which are known in the art, such as a polysulfone-based resin, an acrylic resin, a novolak-based resin, a naphthoquinone-based resin, a hydrocarbon-based resin, a polyimide-based resin, an elastomer resin, etc., can be used. A polysulfone-based resin, a hydrocarbon resin, an acrylic-styrene-based resin, a maleimide-based resin, an elastomer resin, or the like, or a combination thereof, or the like can be more preferably used.

### (Polysulfone-Based Resin)

In the production method of a laminate according to an embodiment, it is preferred that the adhesive for forming the adhesive layer 3 contains a polysulfone-based resin. By forming the adhesive layer 3 with a polysulfone-based resin, even when the laminate 10 is processed at a high temperature, the laminate 10 in which it is possible to dissolve the adhesive layer in the subsequent step to release the support plate from the substrate can be produced.

The polysulfone-based resin has a structure made of at least one structural unit of a polysulfone structural unit that is a structural unit represented by the following general formula (2) and a polyether sulfone structural unit that is a structural unit represented by the following general formula (3).

[Chemical formula 2]

R³—SO₂—R⁴X′R⁵—O (2)

R³—SO₂—R⁴—O (3)

Here, R³, R⁴, and R⁵ in the general formula (2) and R³ and R⁴ in the general formula (3) are each independently selected from the group consisting of a phenylene group, a naphthylene group, and an anthrylene group, and X′ is an alkylene group having 1 or more and 3 or less carbon atoms.

In view of the fact that the polysulfone-based resin includes at least one of the polysulfone structural unit represented by the formula (2) and the polyether sulfone structural unit represented by the formula (3), after bonding the substrate 1 and the support plate 2 to each other, even when the substrate 1 is processed under a high-temperature condition, the laminate 10 which is able to prevent insolubilization of the adhesive layer 3 by decomposition and polymerization, or the like from occurring can be formed. In addition, when the polysulfone-based resin is a polysulfone resin made of the polysulfone structural unit represented by the foregoing formula (2), it is stable even when heated at a higher temperature. For this reason, the generation of a residue in the substrate after cleaning to be caused due to the adhesive layer can be prevented from occurring.

An average molecular weight (Mw) of the polysulfone-based resin is preferably in a range of 30,000 or more and 70,000 or less, and more preferably in a range of 30,000 or more and 50,000 or less. When the average molecular weight (Mw) of the polysulfone-based resin is in a range of 30,000 or more, for example, an adhesive composition that can be used at a high temperature of 300° C. or higher can be obtained. In addition, when the average molecular weight (Mw) of the polysulfone-based resin is in a range of 70,000 or less, the polysulfone-based resin can be suitably dissolved with the solvent. Namely, an adhesive composition that can be suitably removed with the solvent can be obtained.

### (Hydrocarbon Resin)

The hydrocarbon resin is a resin having a hydrocarbon skeleton and formed by polymerizing a monomer composition. Examples of the hydrocarbon resin include a cycloolefin-based polymer (hereinafter sometimes referred to as “resin (A)”), at least one resin selected from the group consisting of a terpene resin, a rosin-based resin, and a petroleum resin (hereinafter sometimes referred to as “resin (B)”), and the like, but it should be construed that the hydrocarbon resin is not limited thereto.

The resin (A) may also be a resin formed by polymerizing a monomer component containing a cycloolefin-based monomer. Specifically, examples thereof include a ring-opened (co)polymer of a monomer component containing a cycloolefin-based monomer, a resin resulting from addition (co)polymerization of a monomer component containing a cycloolefin-based monomer, and the like.

Examples of the cycloolefin-based monomer which is contained in the monomer component constituting the resin (A) include bicyclic monomers, such as norbornene and norbornadiene; tricyclic monomers, such as dicyclopentadiene, and hydroxydicyclopentadiene; tetracyclic monomers, such as tetracyclododecene; pentacyclic monomers, such as a cyclopentadiene trimer; heptacyclic monomers, such as tetracyclopentadiene; or alkyl-(methyl-, ethyl-, propyl-, butyl-, or the like) substituted monomers, alkenyl-(vinyl- or the like) substituted monomers, alkylidene-(ethylidene- or the like) substituted monomers, aryl-(phenyl-, tolyl-, naphthyl-, or the like) substituted monomers, and the like of the foregoing polycyclic monomers. Of these, norbornene-based monomers selected from the group consisting of norbornene, tetracyclododecene, and alkyl-substituted monomers thereof are especially preferred.

The monomer component constituting the resin (A) may contain other monomer which is copolymerizable with the above-described cycloolefin-based monomer. For example, it is preferred to contain an alkene monomer. Examples of the alkene monomer include ethylene, propylene, 1-butene, isobutene, 1-hexene, an α-olefin, and the like. The alkene monomer may be either linear or branched.

In addition, it is preferred that a cycloolefin monomer is contained as the monomer component constituting the resin (A) from the viewpoint of high heat resistance (low thermal decomposition and thermal weight reduction properties). A ratio of the cycloolefin monomer is preferably 5 mol % or more, more preferably 10 mol % or more, and still more preferably 20 mol % or more relative to the whole of the monomer components constituting the resin (A). In addition, though the ratio of the cycloolefin monomer to the whole of the monomer components constituting the resin (A) is not particularly limited, it is preferably 80 mol % or less, and more preferably 70 mol % or less from the viewpoints of solubility and exposure stability in a solution thereof.

In addition, a linear or branched alkene monomer may also be contained as the monomer component constituting the resin (A). A ratio of the alkene monomer is preferably 10 to 90 mol %, more preferably 20 to 85 mol %, and still more preferably 30 to 80 mol % relative to the whole of the monomer components constituting the resin (A) from the viewpoints of solubility and flexibility.

Moreover, it is preferred that the resin (A), for example, as in a resin formed by polymerizing monomer components made of a cycloolefin-based monomer and an alkene monomer, is a resin not having a polar group to suppress the generation of a gas at a high temperature.

The polymerization method and polymerization condition and so on when the monomer components are polymerized are not particularly limited and may be properly set according to the usual way.

Examples of a commercially available product that can be used as the resin (A) include “TOPAS”, manufactured by Polyplastics Co., Ltd.; “APEL”, manufactured by Mitsui Chemicals, Inc.; “ZEONOR” and “ZEONEX”, all of which are manufactured by Zeon Corporation; “ARTON”, manufactured by JSR Corporation; and the like.

A glass transition temperature (Tg) of the resin (A) is preferably 60° C. or higher, and especially preferably 70° C. or higher. When the glass transition temperature of the resin (A) is 60° C. or higher, when the laminate is exposed to a high-temperature environment, softening of the adhesive layer 3 can be more suppressed.

The resin (B) is at least one resin selected from the group consisting of a terpene-based resin, a rosin-based resin, and a petroleum resin. Specifically, examples of the terpene-based resin include a terpene resin, a terpene phenol resin, a denatured terpene resin, a hydrogenated terpene resin, a hydrogenated terpene phenol resin, and the like. Examples of the rosin-based resin include rosin, a rosin ester, a hydrogenated rosin, a hydrogenated rosin ester, a polymerized rosin, a polymerized rosin ester, a denatured rosin, and the like. Examples of the petroleum resin include an aliphatic or aromatic petroleum resin, a hydrogenated petroleum resin, a denatured petroleum resin, an alicyclic petroleum resin, a coumarone-indene petroleum resin, and the like. Of these, a hydrogenated terpene resin and a hydrogenated petroleum resin are more preferred.

Though a softening point of the resin (B) is not particularly limited, it is preferably 80 to 160° C. When the softening point of the resin (B) is 80 to 160° C., when the laminate is exposed to a high-temperature environment, softening can be suppressed, and an adhesive failure does not occur.

Though a weight average molecular weight of the resin (B) is not particularly limited, it is preferably 300 to 3,000. When the weight average molecular weight of the resin (B) is 300 or more, the heat resistance becomes sufficient, and the amount of degasification is reduced in a high-temperature environment. On the other hands, when the weight average molecular weight of the resin (B) is 3,000 or less, a dissolution rate of the adhesive layer into the hydrocarbon-based solvent becomes excellent. For this reason, a residue of the adhesive layer on the substrate after separating the support can be rapidly dissolved and removed. Moreover, the weight average molecular weight of the resin (B) in the present embodiment means a molecular weight in terms of polystyrene measured by means of the gel permeation chromatography (GPC).

Moreover, a mixture of the resin (A) and the resin (B) may be used as the resin. By mixing, the heat resistance becomes excellent. For example, a mixing ratio between the resin (A) and the resin (B) is preferably 80/20 to 55/45 in terms of [(A)/(B)] (mass ratio) because the heat resistance at the time of a high-temperature environment and the flexibility are excellent.

For example, a cycloolefin copolymer that is a copolymer of a repeating unit represented by the following chemical formula (4) and a repeating unit represented by the following chemical (5) can be used as a resin of an adhesive component.

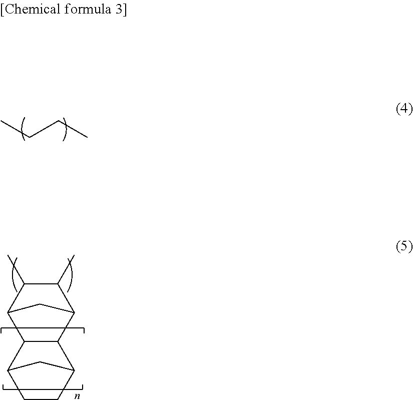

In the chemical formula (5), n is 0 or an integer of 1 to 3.

As such a cycloolefin copolymer, APL 8008T, APL 8009T, and APL 6013T (all of which are manufactured by Mitsui Chemicals, Inc.), and the like can be used.

### (Acrylic-Styrene-Based Resin)

Examples of the acrylic-styrene-based resin include resins which are polymerized using styrene or a styrene derivative and a (meth)acrylic acid ester or the like as monomers.

Examples of the (meth)acrylic acid ester include a (meth)acrylic acid alkyl ester made of a chain structure, a (meth)acrylic acid ester having an aliphatic ring, and a (meth)acrylic acid ester having an aromatic ring. Examples of the (meth)acrylic acid alkyl ester made of a chain structure include an acrylic long-chain alkyl ester having an alkyl group having 15 to 20 carbon atoms, an acrylic alkyl ester having an alkyl group having 1 to 14 carbon atoms, and the like. Examples of the acrylic long-chain alkyl ester include alkyl esters of acrylic acid or methacrylic acid, in which the alkyl group is an n-pentadecyl group, an n-hexadecyl group, an n-heptadecyl group, an n-octadecyl group, an n-nonadecyl group, an n-eicosyl group, or the like. Moreover, the alkyl group may also be branched.

Examples of the acrylic alkyl ester having an alkyl group having 1 to 14 carbon atoms include known acrylic alkyl esters which are used in an existing acrylic adhesive. Examples thereof include alkyl esters of acrylic acid or methacrylic acid, in which the alkyl group is a methyl group, an ethyl group, a propyl group, a butyl group, a 2-ethylhexyl group, an isooctyl group, an isononyl group, an isodecyl group, a dodecyl group, a lauryl group, a tridecyl group, or the like.

Examples of the (meth)acrylic acid ester having an aliphatic ring include cyclohexyl (meth)acrylate, cyclopentyl (meth)acrylate, 1-adamantyl (meth)acrylate, norbornyl (meth)acrylate, isobornyl (meth)acrylate, tricyclodecanyl (meth)acrylate, tetracyclododecanyl (meth)acrylate, dicyclopentanyl (meth)acrylate, and the like. Of these, isobornyl methacrylate and dicyclopentanyl (meth)acrylate are more preferred.

Though the (meth)acrylic acid ester having an aromatic ring is not particularly limited, examples of the aromatic ring include a phenyl group, a benzyl group, a tolyl group, a xylyl group, a biphenyl group, a naphthyl group, an anthracenyl group, a phenoxymethyl group, a phenoxyethyl group, and the like. In addition, the aromatic ring may have a linear or a branched alkyl group having 1 to 5 carbon atoms. Specifically, phenoxyethyl acrylate is preferred.

### (Maleimide-Based Resin)

Examples of the maleimide-based resin include resins obtained by polymerizing, as a monomer, a maleimide having an alkyl group, such as N-methyl maleimide, N-ethyl maleimide, N-n-propyl maleimide, N-isopropyl maleimide, N-n-butyl maleimide, N-isobutyl maleimide, N-sec-butyl maleimide, N-tert-butyl maleimide, N-n-pentyl maleimide, N-n-hexyl maleimide, N-n-heptyl maleimide, N-n-octyl maleimide, N-lauryl maleimide, and N-stearyl maleimide; a maleimide having an aliphatic hydrocarbon group, such as N-cyclopropyl maleimide, N-cyclobutyl maleimide, N-cyclopentyl maleimide, N-cyclohexyl maleimide, N-cycloheptyl maleimide, and N-cyclooctyl maleimide; an aromatic maleimide having an aryl group, such as N-phenyl maleimide, N-m-methylphenyl maleimide, N-o-methylphenyl maleimide, and N-p-methylphenyl maleimide; or the like.

### (Elastomer)

It is preferred that the elastomer contains a styrene unit as a constituent unit of the main chain thereof, and the “styrene unit” may have a substituent. Examples of the substituent include an alkyl group having 1 to 5 carbon atoms, an alkoxy group having 1 to 5 carbon atoms, an alkoxyalkyl group having 1 to 5 carbon atoms, an acetoxy group, a carboxyl group, and the like. In addition, the content of the styrene unit is more preferably in a range of 14% by weight or more and 50% by weight or less. Furthermore, a weight average molecular weight of the elastomer is preferably in a range of 10,000 or more and 200,000 or less.

When the content of the styrene unit is in a range of 14% by weight or more and 50% by weight or less, and the weight average molecular weight of the elastomer is in a range of 10,000 or more and 200,000 or less, the elastomer is easily dissolved in a hydrocarbon-based solvent as described later, and therefore, the adhesive layer can be removed more easily and rapidly. In addition, in view of the fact that the content and weight average molecular weight of the styrene unit fall within the above-described ranges, respectively, the wafer exhibits excellent resistance to a resist solvent (for example, PGMEA, PGME, etc.), an acid (hydrofluoric acid, etc.), and an alkali (TMAH, etc.) to which it is exposed when subjected to a resist lithography step.

Moreover, the elastomer may be further mixed with the above-described (meth)acrylic acid ester.

In addition, the content of the styrene unit is more preferably 17% by weight or more, and more preferably 40% by weight or less.

A more preferred range of the weight average molecular weight is 20,000 or more, and a more preferred range thereof is 150,000 or less.

As for the elastomer, when the content of the styrene unit is in a range of 14% by weight or more and 50% by weight or less, and the weight average molecular weight of the elastomer is in a range of 10,000 or more and 200,000 or less, various elastomers can be used. Examples thereof include a polystyrene-poly(ethylene/propylene) block copolymer (SEP), a styrene-isoprene-styrene block copolymer (SIS), a styrene-butadiene-styrene block copolymer (SBS), a styrene-butadiene-butylene-styrene block copolymer (SBBS), and hydrogenated products thereof; a styrene-ethylene-butylene-styrene block copolymer (SEBS), a styrene-ethylene-propylene-styrene block copolymer (styrene-isoprene-styrene block copolymer) (SEPS), a styrene-ethylene-ethylene-propylene-styrene block copolymer (SEEPS), a styrene-ethylene-ethylene-propylene-styrene block copolymer in which a styrene block thereof is a reaction crosslinking type (e.g., SEPTON V9461 (manufactured by Kuraray Co., Ltd.) or SEPTON V9475 (manufactured by Kuraray Co., Ltd.)), a styrene-ethylene-butylene-styrene block copolymer in which a styrene block thereof is a reaction crosslinking type (SEPTON V9827 (manufactured by Kuraray Co., Ltd.) having a reactive polystyrene-based hard block), a polystyrene-poly(ethylene-ethylene/propylene) block-polystyrene block copolymer (SEEPS-OH; a terminal of which is denatured with a hydroxyl group), and the like. Elastomers in which the content and weight average molecular weight of the styrene unit fall within the above-described ranges, respectively can be used.

In addition, among the elastomers, a hydrogenated product is more preferred. When the elastomer is a hydrogenated product, the stability against heat is improved, and alteration, such as decomposition, polymerization, etc., hardly occurs. In addition, the hydrogenated product is also more preferred from the viewpoints of solubility in the hydrocarbon-based solvent and resistance to the resist solvent.

In addition, among the elastomers, those in which the both terminals thereof are a block polymer of styrene are more preferred. This is because by blocking the both terminals by styrene with high heat stability, higher heat resistance is exhibited.

More specifically, the elastomer is more preferably a hydrogenated product of a block copolymer of styrene and a conjugated diene. In such a hydrogenated product, the stability against heat is improved, and alteration, such as decomposition, polymerization, etc., hardly occurs. In addition, by blocking the both terminals by styrene with high heat stability, higher heat resistance is exhibited. Furthermore, such a hydrogenated product is also more preferred from the viewpoints of solubility in the hydrocarbon-based solvent and resistance to the resist solvent.

Examples of a commercially available product that is usable as the elastomer which is contained in the adhesive constituting the adhesive layer 3 include “SEPTON (trade name)”, manufactured by Kuraray Co., Ltd., “HYBRAR (trade name)”, manufactured by Kuraray Co., Ltd., “TUFTEC (trade name)”, manufactured by Asahi Kasei Corporation, “DYNARON (trade name)”, manufactured by JSR Corporation, and the like.

The content of the elastomer which is contained in the adhesive constituting the adhesive layer 3 is, for example, preferably in a range of 50 parts by weight or more and 99 parts by weight or less, more preferably in a range of 60 parts by weight or more and 99 parts by weight or less, and most preferably in a range of 70 parts by weight or more and 95 parts by weight or less based on 100 parts by weight of the whole amount of the adhesive composition. By allowing the content of the elastomer to fall within the foregoing range, the wafer and the support can be suitably bonded to each other while maintaining the heat resistance.

In addition, as for the elastomer, plural kinds thereof may be mixed. Namely, the adhesive constituting the adhesive layer 3 may contain plural kinds of elastomers. It is enough that at least one of plural kinds of elastomers contains a styrene unit as a constituent unit of the main chain thereof. In addition, as for at least one of the plural kinds of elastomers, so long as the content of the styrene unit is in a range of 14% by weight or more and 50% by weight or less, or the weight average molecular weight is in a range of 10,000 or more and 200,000 or less, such an aspect is encompassed in the scope of the present invention. In addition, in the adhesive constituting the adhesive layer 3, in the case of containing the plural kinds of elastomers, as a result of mixing, the content of the styrene unit may be regulated so as to fall within the above-described range. For example, when SEPTON 4033 of the SEPTON (trade name) series, manufactured by Kuraray Co., Ltd., in which the content of the styrene unit is 30% by weight, and SEPTON 2063 of the SEPTON (trade name) series, in which the content of the styrene unit is 13% by weight, are mixed in a weight ratio of 1/1, the styrene content relative to the whole of the elastomers contained in the adhesive becomes 21 to 22% by weight, and therefore, the content of the styrene unit is 14% by weight or more. In addition, when an elastomer having a styrene unit of 10% by weight and an elastomer having a styrene unit of 60% by weight are mixed in a weight ratio of 1/1, the styrene content relative to the whole of the elastomers contained in the adhesive becomes 35% by weight, and therefore, the content of the styrene unit is in the above-described range. The present invention may be in such a form. In addition, it is most preferred that all of the plural kinds of elastomers contained in the adhesive constituting the adhesive layer 3 contain the styrene unit falling within the above-described range and also have the weight average molecular weight falling within the above-described range.

Moreover, it is preferred that the adhesive layer 3 is formed using a resin other than a photocurable resin (for example, a UV-curable resin). By using the resin other than a photocurable resin, the matter that after stripping or removing the adhesive layer 3, a residue remains on the minute uneven surroundings of the substrate to be supported can be prevented from occurring. In particular, the adhesive constituting the adhesive layer 3 is preferably one which is soluble in a specified solvent but not one which is soluble in all solvents. This is because by dissolving the adhesive layer 3 in a solvent, it is possible remove the adhesive layer 3 without applying a physical force to the substrate 1. On the occasion of removing the adhesive layer 3, the adhesive layer 3 can be easily removed even from the substrate 1, the strength of which has been lowered, without damaging or deforming the substrate 1.

### (Other Components)

In addition, the adhesive constituting the adhesive layer 3 may further contain other miscible substance within a range where essential characteristics are not impaired. For example, commonly used various additives for improving the performance of an adhesive, such as an additive resin, a plasticizer, an adhesion auxiliary substance, a stabilizer, a colorant, a thermal polymerization inhibitor, a surfactant, etc., can be further used.

Moreover, as a diluent solvent which is used at the time of forming the adhesive layer 3, the same solvents as those described above, which are used for the preparation of the reactive polysilsesquioxane, can be used.

### [Lamination Step]

As illustrated in (e) of FIG. 1, the lamination step is a step for forming the laminate 10.

In the lamination step, the substrate 1 having the adhesive layer 3 formed thereon and the support plate 2 having the release layer 4 formed thereon are superimposed under a vacuum condition while heating the adhesive layer 3 in the order of the substrate 1, the adhesive layer 3, the release layer 4, and the support plate 2. Subsequently, the substrate 1 and the support plate 2 superimposed on each other are sandwiched by a pair of plate members included in a bonding apparatus for bonding the laminate, thereby applying a pressure force. According to this, the laminate 10 can be formed. Moreover, the condition for forming the laminate 10 may be properly regulated according to the kind of the adhesive layer and the size of the laminate.

### <Laminate 10>

The laminate 10 produced by the production method of a laminate according to the present embodiment is also encompassed in the scope of the present invention.

As one example, the substrate 1 of the laminate 10 as illustrated in (e) of FIG. 1 is subjected to a thinning processing by a grinding tool, such as a grinder, etc., so as to have a predetermined thickness. In addition, in the laminate 10, a through electrode or the like may be formed going through a photolithography step or the like in, for example, a TSV (through silicone via) process. Since the laminate 10 includes the release layer 4 having high chemical resistance, as formed through polymerization of the reactive polysilsesquioxane, the damage of the release layer 4 to be caused due to various chemicals which are used in the TSV process can be suitably prevented from occurring. In addition, even when the laminate 10 is subjected to a high-temperature processing, the generation of a void between the adhesive layer 3 and the support plate 2 to be caused due to alteration of the release layer 4 can be prevented from occurring.

In addition, when the laminate 10 includes the adhesive layer 3 containing a polysulfone resin, the laminate 10 can be suitably used even in a high-temperature process of performing the processing at a high temperature as 300° C. or higher by means of, for example, annealing or the like.

In addition, in the laminate 10, since the substrate 1 made of silicon is supported by the support plate 2 made of silicon, a coefficient of thermal expansion can be made substantially equal with respect to the substrate 1 and the support plate 2. For this reason, in the laminate 10, when heated in, for example, the TSV process, the high-temperature process, or the like, a strain to be caused due to a difference in the coefficient of thermal expansion between the substrate 1 and the support plate 2 can be reduced. In consequence, the substrate 1 can be subjected to various processings at a high accuracy.

### <Method of Processing Substrate>

Next, the method of processing a substrate according to an embodiment is described. The processing method of a substrate according to an embodiment includes a laminate production step of producing the laminate 10 by the production method of a laminate according to an embodiment ((a) to (e) of FIG. 1) and a separation step of, after the laminate production step, irradiating the release layer 4 with light to alter the release layer 4 and separating the support plate 2 from the laminate 10 ((f) and (g) of FIG. 1).

Since the release layer can be decomposed through irradiation with light, the damage or deformation, or the like of the support plate can be prevented from occurring, and the support plate and the adhesive layer can be easily separated from each other.

### [Separation Step]

As illustrated in (f) of FIG. 1, the release layer 4 is irradiated with light via the support plate 2 in the separation step. According to this, the release layer 4 of the laminate 10 is altered, and the substrate 1 and the support plate 2 are separated from each other ((g) of FIG. 1). Moreover, in the separation step, there may be, for example, adopted a method in which after performing the desired processing, the surface of the laminate 10 on the side of the substrate 1 is bonded to a dicing tape, and the release layer 4 is irradiated with light from the side of the support plate 2. According to this, the substrate 1 having been subjected to the thinning processing can be subjected to the subsequent step while preventing the damage from occurring.

As a laser of emitting light to be irradiated on the release layer 4, there are exemplified typically infrared rays (0.78 μm or more 1,000 μm or less), preferably far-infrared rays (3 μm or more and 1,000 μm or less), and more preferably light having a wavelength of 9 μm or more and 11 μm or less. Specifically, the laser is a CO₂ laser. By using the CO₂ laser, the CO₂ laser is able to transmit through silicon and can be absorbed in the release layer 4 that is a polymer of the reactive polysilsesquioxane. For this reason, by irradiating light from the surface of the laminate 10 on the side of the support plate 2, the release layer 4 can be altered, and the release layer 4 can be made brittle against an external force. In consequence, the substrate 1 and the support plate 2 can be separated from each other by, for example, fixing the substrate 1 in the laminate 10 on a pedestal of a supporting member separation apparatus, holding the support plate 2 by an adsorption pad, and applying a little force. In addition, the substrate 1 and the support plate 2 can also be separated from each other by, for example, grasping a chamfer site of the peripheral edge part of the support plate 2 by a separation plate including a clamp (claw part) to apply a force.

Moreover, since the laminate 10 according to the present embodiment uses the substrate 1 made of silicon, the substrate 1 and the support plate 2 can also be separated from each other by irradiating the release layer 4 with light having a wavelength of 9 μm or more and 11 μm or less from the surface on the side of the substrate 1 to alter the release layer 4.

As for a laser irradiation condition in the separation step, an average output value of the laser light is preferably 1.0 W or more and 5.0 W or less, and more preferably 3.0 W or more and 4.0 W or less. A repetition frequency of the laser light is preferably 20 kHz or more and 60 kHz or less, and more preferably 30 kHz or more and 50 kHz or less. A scanning rate of the laser light is preferably 100 mm/s or more and 10,000 mm/s or less. According to this, the laser irradiation condition can be set to an appropriate condition for altering the release layer 4. In addition, as for a beam spot diameter of a pulse light and an irradiation pitch of the pulse light, it is enough that not only the beam spots adjacent to each other do not overlap, but also the pitch is able to alter the release layer 4.

### [Other Steps]

The substrate 1 from which the support plate 2 has been separated is subjected to other steps, such as a cleaning step, dicing step, etc. According to this, a semiconductor chip is produced from the substrate 1.

In the cleaning step, a residue of the adhesive layer 3 remaining on the substrate 1 and a residue of the release layer 4 are removed with a solvent. As a method for cleaning the substrate 1, the substrate 1 may be cleaned by feeding the solvent into the substrate 1 by means of spraying while spinning the substrate 1. In addition, the substrate 1 may also be cleaned by immersing the substrate 1 in the solvent.

In the cleaning step, the substrate 1 can be cleaned with the solvent as described above in the “(Solvent)”. In addition, in view of the fact that the release layer 4 is the polymer of the reactive polysilsesquioxane, it can be suitably removed with a ketone, such as acetone, methyl ethyl ketone (MEK), cyclohexanone (CH), methyl-n-pentyl ketone, methyl isopentyl ketone, 2-heptanone, etc.

Thereafter, the substrate 1 from which the adhesive layer 3 and the release layer 4 have been removed by the cleaning step is subjected to dicing, whereby the semiconductor chip is produced.

### Another Embodiment

The production method of a laminate according to the present invention is not limited to the above-described embodiments. For example, in the production method of a laminate according to another embodiment, an arbitrary substrate, such as a ceramic substrate, a thin film substrate, a flexible substrate, etc., is used as the substrate, and a support plate made of silicon is used as the support.

Even according to the above-described configuration, the release layer can be formed by polymerizing the reactive polysilsesquioxane on the support plate. In consequence, the laminate including the release layer having high chemical resistance and high heat resistance can be produced, and the release layer can be altered upon irradiation with light having a wavelength of 9 μm or more and 11 μm or less via the support plate. In consequence, the laminate produced by the production method of a laminate according to the present embodiment and the processing method of a substrate including the laminate production step of producing a laminate by the production method of a laminate according to the present embodiment are also encompassed in the scope of the present invention.

In addition, in the production method of a laminate according to still another embodiment, a substrate made of silicon is used as the substrate, and a support plate made of glass, an acrylic resin, or the like is used as the support.

Even according to the above-described configuration, the laminate including the release layer formed of the polymer of the reactive polysilsesquioxane can be produced, and in the laminate, the substrate and the support plate can be suitably separated from each other upon irradiation of the release layer with light via the substrate. In consequence, the laminate produced by the production method of a laminate according to the present embodiment and the processing method of a substrate including the laminate production step of producing a laminate by the production method of a laminate according to the present embodiment are also encompassed in the scope of the present invention.

In addition, in the production method of a laminate according to yet still another embodiment, in the release layer forming step, the release layer which is altered through absorption of light may be formed by coating the reactive polysilsesquioxane on the substrate and heating to polymerize the above-described reactive polysilsesquioxane.

Even according to the above-described configuration, the laminate in which the substrate and the support plate can be suitably separated from each other in the subsequent separation step can be produced. In addition, in the separation step, the matter that when the substrate and the support plate are separated from the laminate, a residue of the adhesive layer remains on the substrate can be prevented from occurring. In consequence, cleaning of the substrate can be more suitably performed.

The embodiments of the present invention are hereunder described in more detail by reference to the following Examples. As a matter of course, the present invention is not limited to the descriptions of the respective embodiments, but may be altered within the scope of the claims. An embodiment derived from a proper combination of technical means disclosed in different embodiments is encompassed in the technical scope of the invention.

### EXAMPLES

A laminate including a release layer formed through polymerization of a reactive polysilsesquioxane was prepared and subjected to evaluation by a high-temperature process and evaluation by a TSV process.

### <Evaluation by High-Temperature Process>

In the evaluation of a laminate in a high-temperature process, as Examples 1 to 4, laminates in which a release layer was formed using a different reactive polysilsesquioxane were prepared and evaluated with respect to heat resistance, warp, and separability of the laminate. In addition, as Comparative Example 1, a laminate in which a release layer was formed using a non-reactive polysilsesquioxane was prepared; as Comparative Example 2, a laminate in which a release layer made of a fluorocarbon was prepared; and these laminates were subjected to the same evaluations as those in Examples 1 to 4.

### [Preparation of Laminate]

First of all, the preparation of a solution for forming the release layer of Example 1 was performed. In Example 1, SR-21 (manufactured by Konishi Chemical Ind. Co., Ltd.) was used as the reactive polysilsesquioxane and dissolved in PGMEA as a solvent such that a ratio of SR-21 was 20% by weight.

Subsequently, the solution of SR-21 was coated on an 8-inch silicon support plate by the spin coating method, and the silicon support plate was heated under a condition at 90° C., 160° C., and 220° C. for 2 minutes, respectively, thereby forming the release layer of Example 1 having a film thickness of 0.8 μm (release layer forming step).

Subsequently, an adhesive in which SUMIKAEXCEL 4800P (polysulfone-based resin, manufactured by Sumitomo Chemical Co., Ltd.) was dissolved in NMP such that a concentration thereof was 20% by mass was prepared. Subsequently, the prepared adhesive was coated on a semiconductor wafer substrate (8-inch silicon) by the spin coating method and baked under a vacuum condition at 90° C., 160° C., and 220° C. for 2 minutes, respectively, thereby forming an adhesive layer (adhesive layer forming step).

Subsequently, the silicon wafer substrate, the adhesive layer, the release layer, and the silicon support plate were superimposed in this order, and a pressure force was applied by a force of 2,000 kg under a vacuum condition and under a temperature condition of 240° C. for 5 minutes, thereby preparing the laminate of Example 1 (lamination step).

In addition, the laminates of Examples 2 to 4 and the laminate of Comparative Example 1 were prepared according to the same procedures as those in Example 1. Moreover, the polysilsesquioxane used for forming the release layer of each of the laminates of Examples 2 to 4 and the laminate of Comparative Example 1 is shown in the following Table 1.

TABLE 1

| | | | Organic | Terminal | Molecular | Siloxane |
|---|---|---|---|---|---|---|
| | Release | | group/ | group/ | weight/ | content/ |
| | layer | | R— | R′O— | Mw | mol % |
| Example 1 | SR | −21 | Phenyl | HO— | 3000 ± 1000 | 95 to 99 |
| Example 2 | | −23 | (PPSQ) | EtO— | 1000 ± 500 | 70 to 90 |
| Example 3 | | −13 | Methyl | EtO— | 6000 ± 1000 | 95 to 99 |
| | | | (PMSQ) | | | |
| Example 4 | | −33 | Methyl/ | EtO— | — | 80 to 99 |
| | | | phenyl | | | |
| | | | (PMPSQ) | | | |
| Compar- | | −20 | Phenyl | — | 6000 ± 1000 | — |
| ative | | | (PPSQ) | | | |
| Example 1 | | | | | | |

The organic group “R—” and the terminal group “R′O—” shown in Table 1 refer to the organic group “R—” and the terminal group “R′O—”, respectively in the structure represented by the following general formula (1).

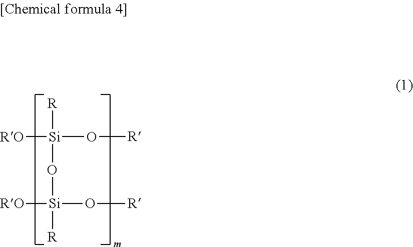

All of SR-21, SR-23, SR-13, SR-33, and SR-20 shown in Table 1 are those manufactured by Konishi Chemical Ind. Co., Ltd.; SR-21, SR-13, SR-23, and R-33 are a reactive polysilsesquioxane; and SR-20 used in Comparative Example 1 is a non-reactive polysilsesquioxane not having a terminal group “R′O—”.

Next, as Comparative Example 2, the laminate in which the release layer made of a fluorocarbon was formed on an 8-inch glass support.

In Comparative Example 2, a bear glass support (8 inches, thickness: 700 μm) was used as a support plate, and a release layer was formed on the support plate by the plasma CVD method using a fluorocarbon. C₄H₈ was used as a reaction gas, and the CVD method was performed under conditions of a flow rate of 400 sccm, a pressure of 700 mTorr, a high-frequency power of 2,500 W, and a film forming temperature of 240° C., thereby forming a fluorocarbon film (thickness: 1 μm) that is the release layer on the support plate. Subsequently, the adhesive layer forming step and the lamination step were performed according to the same procedures as those in Examples 1 to 4 and Comparative Example 1, thereby preparing the laminate of Comparative Example 2.

### [Evaluation of Heat Resistance]

Using each of the laminates of Examples 1 to 4 and the laminates of Comparative Examples 1 and 2, the heat resistance was evaluated. First of all, as the processing of the laminate, the wafer substrate of each of the laminates was thinned with a backgrinding apparatus, manufactured by DISCO Corporation until the thickness became 50 μm. Thereafter, each of the laminates was heat treated in a heating furnace under a condition at 380° C. for 3 hours.

As for the evaluation of heat resistance, the laminate was confirmed through visual inspection. The case where no void was generated between the semiconductor wafer substrate and the glass support was evaluated as “A”, whereas the case where a void was generated was evaluated as “B”. The evaluation results are shown in the following Table 2.

### [Evaluation of Warp]

Next, using each of the laminates of Examples 1 to 4 and the laminates of Comparative Examples 1 and 2, in which the evaluation of heat resistance had been performed, the warp of the laminate was evaluated.

As for the evaluation of warp, a film stress measurement system (TENCOR FLX-2908, manufactured by KLA-Tencor Japan) was used, and the case where the warp of from the center to the peripheral edge of the laminate was 200 μm or less was evaluated as “A”, whereas the case where the warp was larger than 200 μm was evaluated as “B”. The evaluation results are shown in the following Table 2.

### [Evaluation of Separability]

Next, using each of the laminates of Examples 1 to 4 and the laminates of Comparative Examples 1 and 2, the separability between the substrate and the support was evaluated.

Each of the laminates of Examples 1 to 4 and Comparative Example 1 was irradiated with a CO₂ laser light using a CO₂ laser marker, ML-29520-T (manufactured by Keyence Corporation) via the silicon support plate under conditions of a wavelength of 9.3 μm, an output of 20 W (100%), and a scanning rate of 500 mm/s, thereby altering the release layer, and the support was separated from the semiconductor wafer substrate.

In addition, the laminate of Comparative Example 2 was irradiated with a laser light of 532 nm via the glass support, thereby altering the release layer, and the support was separated from the semiconductor wafer substrate.

As for the evaluation of separability, the case where the support plate could be separated from the semiconductor wafer substrate upon irradiation with the laser light was evaluated as “A”, whereas the case where the support plate could not be separated from the semiconductor wafer substrate was evaluated as “B”. The evaluation results are shown in the following Table 2.

TABLE 2

| | | Adhe- | | | Heat | | |
|---|---|---|---|---|---|---|---|
| | Sub- | sive | Release | Support | resis- | | Separa- |
| | strate | layer | layer | plate | tance | Warp | bility |
| Example 1 | Silicon | 4800P | SR-21 | Silicon | A | A | A |
| Example 2 | Silicon | 4800P | SR-23 | Silicon | A | A | A |
| Example 3 | Silicon | 4800P | SR-13 | Silicon | A | A | A |
| Example 4 | Silicon | 4800P | SR-33 | Silicon | A | A | A |
| Compar- | Silicon | 4800P | SR-20 | Silicon | B | A | A |
| ative | | | | | | | |
| Example 1 | | | | | | | |
| Compar- | Silicon | 4800P | Fluoro- | Glass | B | B | A* |
| ative | | | carbon | | | | |
| Example 2 | | | | | | | |

*The evaluation was performed upon irradiation with light having a wavelength of 532 nm.

As shown in Table 2, in the evaluation of heat resistance, in the laminates of Examples 1 to 4, the generation of a void between the substrate and the support plate was not perceived (A). On the other hand, in the laminates of Comparative Examples 1 and 2, the generation of a void was confirmed (B). In consequence, it could be confirmed that the laminate using the reactive polysilsesquioxane can be suitably used for the processing at a high temperature (380° C.) for a long time (3 hours) as compared with the laminate using the non-reactive polysilsesquioxane as the release layer and the laminate using the fluorocarbon as the release layer.

In addition, in the laminates of Examples 1 to 4 and the laminate of Comparative Example 1, each using silicon as the substrate and the support plate, the warp of the laminate was 200 μm or less (A). On the other hand, the warp of the laminate of Comparative Example 2 using the glass support for the support plate was larger than 200 μm (B). In consequence, it could be confirmed that by using silicon for the substrate and the support plate, even by performing the processing at a high temperature for a long time, the strain generated in the laminate can be reduced.

In the evaluation of separability, in all of the laminates, the substrate and the support plate could be suitably separated from each other only by applying a little force (A). Moreover, in the laminate of Comparative Example 2, the light having a wavelength of 532 nm was irradiated, and in the case of using the CO₂ laser, the release layer made of the fluorocarbon could not be altered.

From the above-described evaluation results, it could be confirmed that the laminates of Examples 1 to 4 include the release layer with high heat resistance and are less in the strain at a high temperature, and by irradiating the release layer with light, the substrate and the support plate can be suitably separated from each other. In consequence, it is judged that the laminate according to the present invention can be suitably used for the purpose of processing the substrate by the high-temperature process.

### <Evaluation by TSV Process>

Next, the laminate in the TSV process was evaluated. As Examples 5 to 8, laminates in which a release layer was formed using a different reactive polysilsesquioxane were prepared and evaluated with respect to chemical resistance, heat resistance, warp, and releasability of the laminate. In addition, as Comparative Example 3, a laminate in which a release layer was formed using a non-reactive polysilsesquioxane was prepared; as Comparative Example 4, a laminate in which a release layer made of a fluorocarbon was formed was prepared; and these laminates were subjected to the same evaluations as those in Examples 5 to 8.

### [Preparation of Laminate]

The laminates of Examples 5 to 8 and the laminate of Comparative Example 3 were formed according to the same procedures as those in Example 1, except that a semiconductor wafer substrate (12-inch silicon) was used as the substrate, a 12-inch silicon support plate was used as the support, and TZNR (registered trademark) A4017 (manufactured by Tokyo Ohka Kogyo Co., Ltd.) was used as the adhesive for forming the adhesive layer. In addition, the laminate of Comparative Example 4 was prepared in the same procedures as those in Comparative Example 2, except that the same substrate and adhesive were used in the same procedures as those in Example 5, and a 12-inch glass support was used. The configuration of each of the laminates of Examples 5 to 8 and the laminates of Comparative Examples 3 and 4 is shown in the following Table 3.

### [Evaluation of Chemical Resistance]

Using each of the laminates of Examples 5 to 8 and the laminates of Comparative Examples 3 and 4, the heat resistance was evaluated. First of all, as the processing of the laminate, the wafer substrate of each of the laminates was thinned with a backgrinding apparatus, manufactured by DISCO Corporation until the thickness became 50 μm. Thereafter, each of the laminates was immersed in N-methyl-2-pyrrolidone (NMP) at 60° C. for 10 minutes and evaluated in terms of the chemical resistance.

As for the evaluation of chemical resistance, after immersing the laminate in NMP, whether or not the release layer was swollen was judged through visual inspection. The case where the laminate was not swollen was evaluated as “A”, whereas the case where the laminate was swollen was evaluated as “B”. The evaluation results are shown in the following Table 3.

### [Evaluation of Heat Resistance]

Next, using each of the laminates of Examples 5 to 8 and the laminates of Comparative Examples 3 and 4, in which the evaluation of chemical resistance had been performed, the heat resistance was evaluated. As for the evaluation of heat resistance, each of the laminates was heated under a vacuum condition at 220° C. for 10 minutes, and subsequently, each of the laminates was heated under atmospheric pressure and under a condition at 260° C. for 60 minutes.

As for the evaluation of heat resistance, the laminate was confirmed through visual inspection, and the case where no void was generated between the semiconductor wafer substrate and the glass support was evaluated as “A”, whereas the case where a void was generated was evaluated as “B”. The evaluation results are shown in the following Table 3.

### [Evaluation of Warp]

Next, using each of the laminates of Examples 5 to 8 and the laminates of Comparative Examples 3 and 4, in which the evaluation of heat resistance had been performed, the warp of the laminate was evaluated.

Moreover, the evaluation of warp was performed by the same method as that in the evaluation of warp in the evaluation of the high-temperature process. The results are shown in the following Table 3.

### [Evaluation of Separability]

Next, using each of the laminates of Examples 5 to 8 and the laminates of Comparative Examples 3 and 4, the separability between the substrate and the support was evaluated. Moreover, in each of the laminates of Examples 5 to 8 and Comparative Example 3, the release layer was irradiated with light under the same condition as that in Example 1, and the separability was evaluated. In addition, in the laminate of Comparative Example 4, the release layer was irradiated with light under the same condition as that in Comparative Example 2, and the separability was evaluated. The evaluation results are shown in the following Table 3.

TABLE 3

| | | | Release | Support | Chemical | Heat | | |
|---|---|---|---|---|---|---|---|---|
| | Substrate | Adhesive | layer | plate | resistance | resistance | Warp | Separability |
| Example 5 | Silicon | A4017 | SR-21 | Silicon | A | A | A | A |
| Example 6 | Silicon | A4017 | SR-23 | Silicon | A | A | A | A |
| Example 7 | Silicon | A4017 | SR-13 | Silicon | A | A | A | A |
| Example 8 | Silicon | A4017 | SR-33 | Silicon | A | A | A | A |
| Comparative | Silicon | A4017 | SR-20 | Silicon | B | A | A | A |
| Example 3 | | | | | | | | |
| Comparative | Silicon | A4017 | Fluorocarbon | Glass | B | A | B | A* |
| Example 4 | | | | | | | | |

*The evaluation was performed upon irradiation with light having a wavelength of 532 nm.

As shown in Table 3, in the evaluation of chemical resistance, in the laminates of Examples 5 to 8, swelling of the release layer was not perceived (A). On the other hand, in the laminate of Comparative Example 3, swelling of the release layer was confirmed. In consequence, it could be confirmed that the laminate using the reactive polysilsesquioxane for the release layer is higher in the chemical resistance than the laminate using the non-reactive polysilsesquioxane for the release layer.

In addition, as shown in Table 3, in the evaluation of heat chemical, in the laminates of Examples 5 to 8, the generation of a void between the substrate and the support plate was not perceived (A). In consequence, the laminates of Examples 5 to 8 exhibit high heat resistance even under a condition at 260° C., and hence, it is judged that these laminates can be suitably used in the TSV process.

In addition, in the laminates of Examples 5 to 8, each using silicon as the substrate and the support plate, the warp of the laminate was 200 μm or less (A). On the other hand, the warp of the laminate of Comparative Example 4 using the glass support for the support plate was larger than 200 μm (B).

In the evaluation of separability, in all of the laminates, the substrate and the support plate could be suitably separated from each other only by applying a little force (A). Moreover, in the laminate of Comparative Example 4, the light having a wavelength of 532 nm was irradiated, and in the case of using the CO₂ laser, the release layer made of the fluorocarbon could not be altered.

From the above-described evaluation results, it could be confirmed that the laminates of Examples 5 to 8 include the release layer with high chemical resistance and high heat resistance and are less in the strain at a high temperature, and by irradiating the release layer with light, the substrate and the support plate can be suitably separated from each other. In consequence, it is judged that the laminate according to the present invention can be suitably used for the purpose of processing the substrate by the TSV process.

### INDUSTRIAL APPLICABILITY

The present invention can be suitably utilized in the production process of a miniaturized semiconductor device.

### REFERENCE SIGNS LIST

1: Substrate
2: Support plate (support)
3: Adhesive layer
4: Release layer
10: Laminate

1. A method of producing a laminate in which a substrate and a light-transmitting support are laminated via an adhesive layer and a release layer that is altered through absorption of light,
the method comprising a release layer forming step of coating a reactive polysilsesquioxane having a structure represented by the following formula (1) on a surface of the support, the surface being opposed to the substrate, and heating the reactive polysilsesquioxane to mutually condense Si—O—R′ bonds which the reactive polysilsesquioxane has, thereby achieving polymerization to form the release layer: 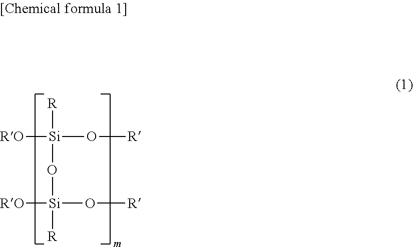
wherein R each independently is selected from the group consisting of organic groups, R′ each independently is selected from the group consisting of a hydrogen atom and an alkyl group having 1 or more and 10 or less carbon atoms, and m is an integer of 1 or more and 100 or less.

2. The method of producing a laminate according to claim 1, wherein R in the formula (1) each independently is selected from the group consisting of an aryl group and an alkyl group.

3. The method of producing a laminate according to claim 1, wherein in the release layer forming step, the reactive polysilsesquioxane having a structure represented by the formula (1) is heated at a temperature of 100° C. or higher.

4. The method of producing a laminate according to claim 1, wherein the support is made of silicon.

5. The method of producing a laminate according to claim 1, wherein the adhesive layer contains a polysulfone-based resin.

6. A method of producing a laminate in which a substrate and a light-transmitting support are laminated via an adhesive layer and a release layer that is altered through absorption of light,
the method comprising a release layer forming step of coating a reactive polysilsesquioxane on a surface of the support, the surface being opposed to the substrate, and heating the reactive polysilsesquioxane to perform polymerization, thereby forming the release layer,
wherein the adhesive layer contains a polysulfone-based resin.

7. A method of processing a substrate, comprising
a laminate production step of producing a laminate by the production method according to claim 1; and
after the laminate production step, a separation step of irradiating the release layer with light to alter the release layer and separating the support from the laminate.

8. A method of processing a substrate, comprising:
a release layer forming step of coating a reactive polysilsesquioxane having a structure represented by the following formula (1) on a substrate or a support made of silicon and heating the reactive polysilsesquioxane to mutually condense Si—O—R′ bonds which the reactive polysilsesquioxane has, thereby achieving polymerization to form a release layer that is altered through absorption of light: 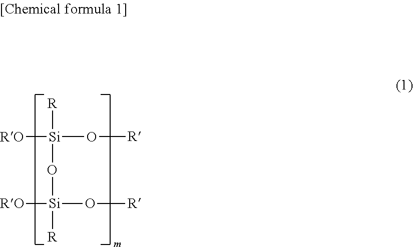
wherein R each independently is selected from the group consisting of organic groups, R′ each independently is selected from the group consisting of a hydrogen atom and an alkyl group having 1 or more and 10 or less carbon atoms, and m is an integer of 1 or more and 100 or less;
a laminate production step of laminating the substrate and the support via an adhesive layer and the release layer to produce a laminate; and
after the laminate production step, a separation step of irradiating light having a wavelength of 9 μm or more and 11 μm or less to alter the release layer and separating the support from the laminate.

9. The method of processing a substrate according to claim 8, wherein R in the formula (1) each independently is selected from the group consisting of an aryl group and an alkyl group.

10. The method of processing a substrate according to claim 8, wherein in the release layer forming step, the reactive polysilsesquioxane having a structure represented by the formula (1) is heated at a temperature of 100° C. or higher.

11. The method of processing a substrate according to claim 8, wherein the adhesive layer contains a polysulfone-based resin.

12. The method of processing a substrate according to claim 7, comprising, after the laminate production step and before the separation step, heating the laminate at a temperature of 260° C. or higher.

13. A laminate in which a substrate and a support which supports the substrate are laminated via an adhesive layer and a release layer that is altered through absorption with light,
the release layer being formed of a polymer prepared through polymerization by mutually condensing Si—O—R′ bonds which a reactive polysilsesquioxane has, the reactive polysilsesquioxane having a structure represented by the following formula (1): 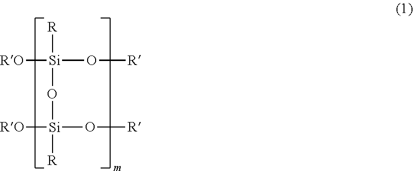
wherein R each independently is selected from the group consisting of organic groups, R′ each independently is selected from the group consisting of a hydrogen atom and an alkyl group having 1 or more and 10 or less carbon atoms, and m is an integer of 1 or more and 100 or less.

14. The laminate according to claim 13, wherein R in the formula (1) each independently is selected from the group consisting of an aryl group and an alkyl group.

15. The laminate according to claim 13, wherein the reactive polysilsesquioxane having a structure represented by the formula (1) is heated at a temperature of 100° C. or higher to mutually condense Si—O—R′ bonds which the reactive polysilsesquioxane has.

16. The laminate according to claim 13, wherein the support is made of silicon.

17. The laminate according to claim 13, wherein the adhesive layer contains a polysulfone-based resin.

18. The laminate according to claim 13, wherein the laminate is heated at a temperature of 260° C. or higher.

19. A laminate comprising a substrate and a support which supports the substrate that are laminated each other via an adhesive layer and a release layer that is altered through absorption with light,
the release layer being formed of a polymer of a reactive polysilsesquioxane; and
the adhesive layer containing a polysulfone-based resin.
